(19) United States
(12) Patent Application Publication
(10) Pub. No.: US 2026/0301622 A1
(43) Pub. Date: Oct. 1, 2026

(54) DISPLAY APPARATUS AND ELECTRONIC DEVICE INCLUDING THE SAME

(71) Applicant: Samsung Display Co., Ltd., Yongin-si (KR)

(72) Inventors: SUNKWANG KIM, Yongin-si (KR); SEUNGSOO BAEK, Yongin-si (KR); SI HYUN AHN, Yongin-si (KR); KYEUK LEE, Yongin-si (KR); SEONGYOUNG LEE, Yongin-si (KR)

(73) Assignee: Samsung Display Co., Ltd., Yongin-si (KR)

(21) Appl. No.: 19/570,821

(22) Filed: Mar. 18, 2026

(30) Foreign Application Priority Data
Mar. 26, 2025 (KR) 10-2025-0038746

(51) Int. Cl. G09G 3/00; G09G 3/3233; H10K 59/88

(52) U.S. Cl. CPC G09G 3/006; G09G 3/3233; H10K 59/88; G09G 2300/0413; G09G 2300/0819; G09G 2300/0852; G09G 2300/0861; G09G 2330/08; G09G 2330/12

(57) ABSTRACT

A display apparatus includes at least one light-emitting pixel in a display area of the display apparatus and including a plurality of sub-light-emitting pixels, and at least one dummy pixel unit in a dummy area of the display apparatus, and connected to a repair line configured to be connected to at least one light-emitting device, the at least one dummy pixel unit including a plurality of sub-dummy pixels respectively corresponding to the plurality of sub-light-emitting pixels, where a first sub-dummy pixel from among the plurality of sub-dummy pixels is a repair sub-dummy pixel, and a second sub-dummy pixel from among the plurality of sub-dummy pixels is an auxiliary sub-dummy pixel configured for an automatic optical inspection.

### CROSS-REFERENCE TO RELATED APPLICATION

This application is based on and claims priority under 35 USC § 119 to Korean Patent Application No. 10-2025-0038746, filed on Mar. 26, 2025, in the Korean Intellectual Property Office, the disclosure of which is incorporated by reference herein in its entirety.

### BACKGROUND

### 1. Field

The disclosure relates to a display apparatus and an electronic device including the same.

### 2. Description of Related Art

Display apparatuses may refer to apparatuses that receive information regarding images and display the images. Display apparatuses may be used as display units for small products such as mobile phones, or as display units for large products such as televisions.

A display apparatus may include a plurality of pixels that receive electrical signals and emit light to display an image externally. Each of the pixels may include a light-emitting device. For example, an organic light-emitting display apparatus may include an organic light-emitting diode (OLED) as a light-emitting device. In general, the organic light-emitting display apparatus may operate in the case where a thin film transistor and an OLED are formed on a substrate and the OLED emits light.

Electronic devices may provide users with needed visual interfaces through display apparatuses.

Defective pixels may be generated during processes of manufacturing display apparatuses. In the case where defects occur in particular pixels, the particular pixels may always generate light regardless of scan signals and data signals. As described above, from among pixels, pixels that always generate light may be recognized as bright spots (or luminous spots) by observers, and the bright spots may be easily observed by the observers due to high visibility.

Organic light-emitting display apparatuses may have complex pixel circuits and uneasy manufacturing processes, and thus, as the organic light-emitting display apparatuses become larger and have higher resolutions, yield may decrease.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided is a display apparatus that may be inspected for a defect in a dummy pixel through an automatic optical inspection (AOI).

Additional aspects will be set forth in part in the description which follows and, in part, will be apparent from the description, or may be learned by practice of the presented embodiments.

According to an aspect of the disclosure, a display apparatus may include at least one light-emitting pixel in a display area of the display apparatus and including a plurality of sub-light-emitting pixels, and at least one dummy pixel unit in a dummy area of the display apparatus, and connected to a repair line that is connected to at least one light-emitting device, the at least one dummy pixel unit including a plurality of sub-dummy pixels respectively corresponding to the plurality of sub-light-emitting pixels, where a first sub-dummy pixel from among the plurality of sub-dummy pixels is a repair sub-dummy pixel, and a second sub-dummy pixel from among the plurality of sub-dummy pixels is an auxiliary sub-dummy pixel configured for an automatic optical inspection.

The first sub-dummy pixel may be configured to be driven after a repair process, and the second sub-dummy pixel may be configured not to be driven.

After the repair process, the first sub-dummy pixel may be configured to be supplied with a first data signal through a data line, and the second sub-dummy pixel may be configured to be supplied with a second data signal that is different from the first data signal through a dummy data line.

The plurality of sub-dummy pixels may include pixel circuits respectively corresponding to the plurality of sub-light-emitting pixels.

The plurality of sub-dummy pixels may not include light-emitting devices respectively corresponding to the plurality of sub-light-emitting pixels.

The at least one dummy pixel unit may include a first layer and the at least one light-emitting pixel may include a second layer and the first layer has a same pattern and a same material as the second layer.

A dummy pixel unit among the at least one dummy pixel unit that corresponds to the at least one light-emitting pixel may be in a same row as the at least one light-emitting pixel.

The at least one dummy pixel unit may include a plurality of dummy pixel units corresponding to the at least one light-emitting pixel, and a first dummy pixel unit among the plurality of dummy pixel units is adjacent to a boundary of the display area, and a second dummy pixel unit among the plurality of dummy pixel units is adjacent to the first dummy pixel unit.

The first dummy pixel unit may include a repair sub-dummy pixel.

The display device may include an additional sub-dummy pixel adjacent to the at least one dummy pixel unit.

The at least one light-emitting pixel may include a plurality of light-emitting pixels in the display area, among the plurality of light-emitting pixels, a first light-emitting pixel and a second light-emitting pixel adjacent to the first light-emitting pixel may include same patterns, and the at least one dummy pixel unit is adjacent to the display area and includes a same pattern as the first light-emitting pixel and the second light-emitting pixel.

According to an aspect of the disclosure, an electronic device may include a controller configured to generate a scan input signal, a power module configured to generate a scan input voltage, and a display module including a display panel divided into a display area including a pixel circuit and a dummy area and a scan driver in the dummy area, the scan driver configured to receive the scan input signal and the scan input voltage, and output a scan signal to the pixel circuit, where the display panel may include a light-emitting pixel in the display area and including a plurality of sub-light-emitting pixels, and at least one dummy pixel unit in the dummy area and connected to a repair line that is connected to at least one light-emitting device, the at least one dummy pixel unit including a plurality of sub-dummy pixels respectively corresponding to the plurality of sub-light-emitting pixels, where a first sub-dummy pixel from among the plurality of sub-dummy pixels of the at least one dummy pixel unit is a repair sub-dummy pixel, and a second sub-dummy pixel from among the plurality of sub-dummy pixels is an auxiliary sub-dummy pixel configured for an automatic optical inspection.

During a repair process, the first sub-dummy pixel may be configured to be driven, and the second sub-dummy pixel may be configured to be limitedly driven.

During the repair process, the first sub-dummy pixel may be configured to be supplied with a first data signal through a data line, and the second sub-dummy pixel may be configured to be supplied with a second data signal that is different from the first data signal through a dummy data line.

The plurality of sub-dummy pixels may include pixel circuits respectively corresponding to the plurality of sub-light-emitting pixels.

The plurality of sub-dummy pixels may not include light-emitting devices respectively corresponding to the plurality of sub-light-emitting pixels.

The at least one dummy pixel unit may include a first layer and the at least one light-emitting pixel may include a second layer and the first layer has a same pattern and a same material as the second layer.

A dummy pixel unit among the at least one dummy pixel unit that corresponds to the at least one light-emitting pixel may be in a same row as the at least one light-emitting pixel.

The at least one dummy pixel unit may include a plurality of dummy pixel units corresponding to the at least one light-emitting pixel, and a first dummy pixel unit among the plurality of dummy pixel units is adjacent to a boundary of the display area, and a second dummy pixel unit among the plurality of dummy pixel units is adjacent to the first dummy pixel unit.

The first dummy pixel unit may include a repair sub-dummy pixel.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram schematically illustrating a display apparatus according to an embodiment;

FIGS. 2 and 3 are diagrams schematically illustrating examples of a display panel illustrated in FIG. 1 according to an embodiment;

FIGS. 4 and 5 are diagrams illustrating a method of repairing a defective pixel by using a repair line, according to an embodiment;

FIG. 6 is a circuit diagram of a light-emitting pixel according to an embodiment;

FIG. 7 is a circuit diagram illustrating a light-emitting pixel and a dummy pixel according to an embodiment;

FIG. 8 is a circuit diagram illustrating a light-emitting pixel and a dummy pixel according to an embodiment;

FIG. 9 is a diagram illustrating a display panel inspected by an optical inspection method for a display panel;

FIG. 10 is a diagram schematically illustrating a light-emitting pixel and a dummy pixel according to a comparative example;

FIG. 11 is a diagram schematically some light-emitting pixels and dummy pixels of a display apparatus, according to an embodiment;

FIG. 12 is a diagram schematically illustrating a portion of a light-emitting pixel and a dummy pixel of a display apparatus, according to an embodiment;

FIG. 13 is a diagram schematically illustrating a line connection between a light-emitting pixel and a dummy pixel below a panel of a display apparatus, according to an embodiment;

FIG. 14 is a plan view of a pixel array of a display apparatus including a pixel circuit of FIG. 8, according to an embodiment;

FIG. 15 is a plan view illustrating a pixel array before a light-emitting device is formed in a display apparatus including the pixel circuit of FIG. 8, according to an embodiment;

FIG. 16 is a plan view illustrating a pixel array formed from a pixel array of FIG. 7 to a light-emitting device according to an embodiment; and

FIG. 17 is a block diagram of an electronic device according to embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In the embodiments below, the terms “comprise or include” or “have” refer to the presence of features or components described herein and do not preclude the possibility of one or more other features or components being added.

In the following embodiments, the terms “connect” or “combine” do not necessarily mean a direct and/or fixed connection or combination of two members unless the context clearly indicates otherwise, and do not preclude another member intervening between the two members.

For convenience of description, sizes of components may be exaggerated or reduced in the drawings. For example, the size and/or thickness of each component shown in the drawings are randomly shown for convenience of description, and thus, the disclosure is not necessarily limited to that illustrated.

The terms used herein to describe a space, a direction, and the like refer to the terms for describing a space and a direction illustrated in the drawings, but may be understood as the terms for describing other various directions or various viewpoints. For example, in the case where an apparatus or a component illustrated in the drawings is overturned, the apparatus or the component described as being “below” may be interpreted to be in a different direction (e.g., may be interpreted to rotate 90 degrees, to be in the opposite direction, or the like). For example, in the case where an apparatus or a component illustrated in the drawings is overturned, the apparatus or the component described as being “on” may be interpreted to be in a different direction (e.g., may be interpreted to rotate 90 degrees, be in the opposite direction, or the like). Therefore, the terms “below” and “on” may include both upward and downward directions. In addition, the apparatus or the component may be oriented differently from the drawings, and the description according to the space or direction described herein may be interpreted in various ways.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

Hereinafter, embodiments are described in detail with reference to the accompanying drawings, and when described with reference to the drawings, the same or corresponding components are given the same reference numerals, and the same descriptions thereof are omitted.

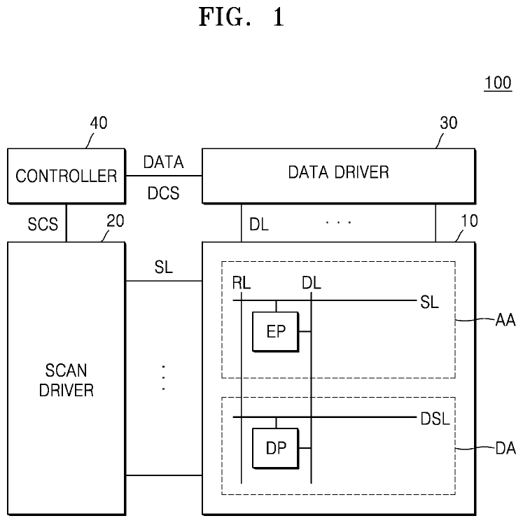

FIG. 1 is a block diagram schematically illustrating a display apparatus according to an embodiment.

Referring to FIG. 1, a display apparatus 100 may include a display panel 10, a scan driver 20, a data driver 30, and a controller 40. The scan driver 20, the data driver 30, and the controller 40 may be respectively formed on separate semiconductor chips or may be integrated on one semiconductor chip. The scan driver 20 may also be formed on the same substrate as the display panel 10.

A display area AA and a dummy area DA adjacent to the display area AA may be formed on the display panel 10. The dummy area DA may be formed in at least one area from among an area above the display area AA and an area below the display area AA. In one or more embodiments, the dummy area DA may be in at least one area to the left and to the right of the display area AA, and the dummy area DA may be constructed to surround the display area AA in plan view. A plurality of light-emitting pixels EP connected to a scan line SL and a data line DL may be arranged in the display area AA, and a plurality of dummy pixels DP connected to a dummy scan line DSL and the data line DL may be arranged in the dummy area DA. The display panel 10 may be provided with a repair line RL parallel to the data line DL, in each pixel column. The repair line RL may connect a light-emitting device of a defective light-emitting pixel EP to a dummy pixel DP. The repair line RL may provide a path for transmitting a driving current generated by the dummy pixel DP to the defective light-emitting pixel EP.

The scan driver 20 may generate a scan signal and sequentially supply the scan signal to the light-emitting pixels EP through a plurality of scan lines SL. The scan driver 20 may generate a dummy scan signal and supply the dummy scan signal to the dummy pixel DP through the dummy scan line DSL. The dummy scan line DSL may be a scan line preceding a first scan line or a scan line following a last scan line in the display area AA. Accordingly, the dummy scan signal may be a scan signal preceding a first scan signal or a scan signal following a last scan signal in the display area AA.

The data driver 30 may supply a data signal to the light-emitting pixels EP through a plurality of data lines DL. The data driver 30 may convert input image data DATA having a grayscale, which is input from the controller 40, into a data signal in the form of a voltage or current.

In the case where a light-emitting pixel EP in the same pixel column is defective, and where a light-emitting device of the defective light-emitting pixel EP and the dummy pixel DP are connected to the repair line RL as shown in FIG. 1, the same data signal as a data signal applied to or to be applied to the light-emitting pixel EP connected to the repair line RL may be applied to the dummy pixel DP, and thus, the light-emitting pixel EP connected to the repair line RL may emit light.

The controller 40 may generate a scan control signal SCS and a data control signal DCS and transmit the scan control signal SCS and the data control signal DCS to the scan driver 20 and the data driver 30, respectively. Accordingly, the scan driver 20 may sequentially apply the scan signal to the scan line SL and the dummy scan line DSL, and in response to the scan signal, the data driver 30 may apply the data signal to the light-emitting pixel EP and the dummy pixel DP.

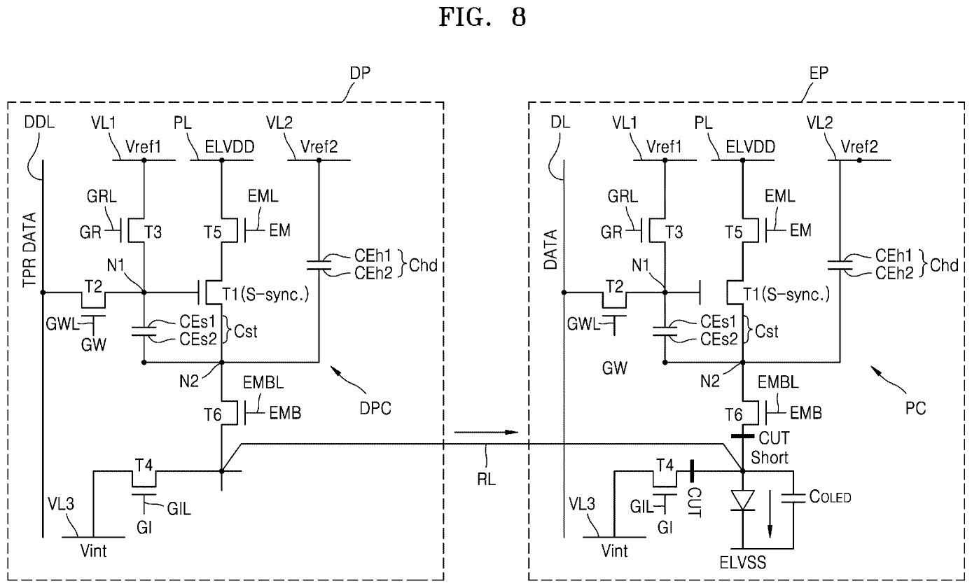

According to a configuration of a pixel and a driving method of a display apparatus, a first power voltage (ELVDD; see FIG. 8), a second power voltage (ELVSS; see FIG. 8), a reference voltage (Vref1, Vref2; see FIG. 8), a plurality of control signals (GC, GW, GS, and GE; see FIG. 8), and the like may be applied to the light-emitting pixel EP and the dummy pixel DP under control of the controller 40.

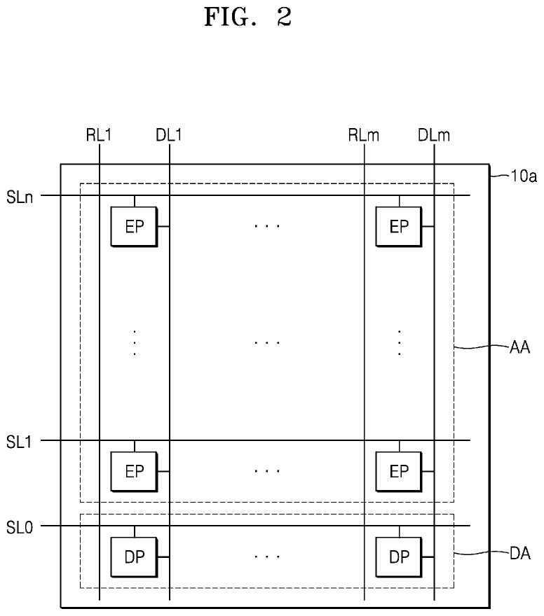

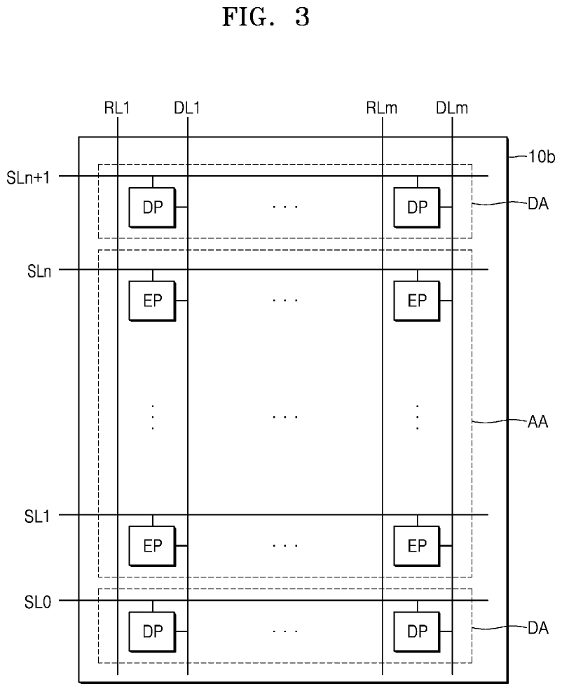

FIGS. 2 and 3 are diagrams schematically illustrating examples of a display panel illustrated in FIG. 1 according to an embodiment.

A dummy area DA may be formed in at least one area, from among areas above and below a display area AA or areas on the left and right sides of the display area AA. Accordingly, one or more dummy pixels DP may be formed in each pixel column in at least one area above and below a pixel column, or in each pixel row in at least one area on the left and right of the pixel row. FIGS. 2 and 3 illustrate an example in which dummy pixels DP are formed in pixel columns in dummy areas DA above and below the display area AA, and the above example may be equally applied to a case where the dummy pixels DP are formed in pixel rows in dummy areas DA on the left and right of the display area AA.

However, the embodiments of the disclosure are not limited thereto, and the dummy pixels DP may also be formed by repeatedly extending in a row direction or a column direction in every tens or hundreds of pixel rows or pixel columns within the display area AA.

Referring to FIG. 2, a plurality of scan lines SL1 to SLn, a plurality of data lines DL1 to DLm, a plurality of repair lines RL1 to RLm, and a dummy scan line SL0 may be formed on a display panel 10a. A plurality of light-emitting pixels EP connected to the plurality of scan lines SL1 to SLn and the plurality of data lines DL1 to DLm may be formed in the display area AA, and a plurality of dummy pixels DP connected to the dummy scan line SL0 and the plurality of data lines DL1 to DLm may be formed in the dummy area DA.

The dummy scan line SL0 may be a 0^{th} scan line before a first scan line SL1 in the display area AA, and may receive a 0^{th} scan signal prior to a first scan signal applied to the first scan line SL1. The plurality of data lines DL1 to DLm and the plurality of repair lines RL1 to RLm may be formed in respective pixel columns in the display area AA and the dummy area DA.

Referring to FIG. 3, a plurality of scan lines SL1 to SLn, a plurality of data lines DL1 to DLm, a plurality of repair lines RL1 to RLm, and a first dummy scan line SL0 and a second dummy scan lines SLn+1 may be formed on a display panel 10b. A plurality of light-emitting pixels EP connected to the plurality of scan lines SL1 to SLn and the plurality of data lines DL1 to DLm may be formed in a display area AA. A plurality of dummy pixels DP connected to the first dummy scan line SL0, the second dummy scan line SLn+1, and the plurality of data lines DL1 to DLm may be formed in a dummy area DA.

The first dummy scan line SL0 may be a 0^{th} scan line before a first scan line SL1 in the display area AA, and may receive a 0^{th} scan signal before a first scan signal applied to the first scan line SL1. The second dummy scan line SLn+1 may be an n^{th+}1 scan line after the last n^{th} scan line SLn in the display area AA, and may receive an n^{th}+1 scan signal after an n^{th} scan signal applied to the n^{th} scan line SLn. The plurality of data lines DL1 to DLm and the plurality of repair lines RL1 to RLm may be formed in respective pixel columns in the display area AA and the dummy area DA.

Although FIGS. 2 and 3 illustrate one dummy pixel DP in each pixel column in each dummy area DA, the embodiments of the disclosure are not limited thereto, and one or more dummy pixels DP may be formed in each pixel column in the dummy area DA.

Alternatively, in the case where the dummy areas DA are formed in one or more areas from among areas on the left and right of the display area AA, one or more dummy pixels DP may be formed in each pixel row in the dummy area DA.

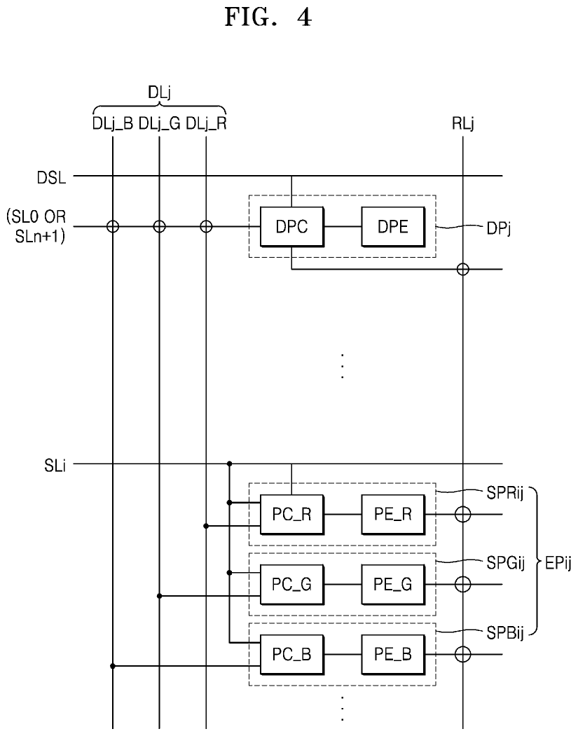

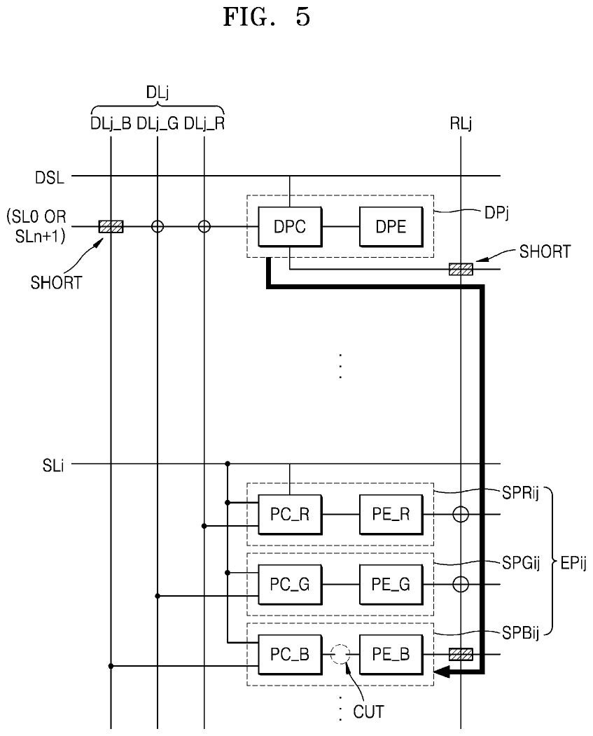

FIGS. 4 and 5 are views illustrating a method of repairing a defective pixel by using a repair line, according to an embodiment.

Referring to FIG. 4, a light-emitting pixel EPij may be connected to a scan line SLi in an i^{th} pixel row and a data line DLj in a j^{th} pixel column. The light-emitting pixel EPij may include a plurality of sub-light-emitting pixels. Each of the sub-light-emitting pixels may emit one color, e.g., one color from among red, blue, green, and white. However, embodiments are not limited thereto, and the sub-light-emitting pixel may emit a color other than red, blue, green, and white. The embodiment of FIG. 4 illustrates an example in which the light-emitting pixel EPij includes a red sub-light-emitting pixel SPRij, a green sub-light-emitting pixel SPGij, and a blue sub-light-emitting pixel SPBij.

The plurality of sub-light-emitting pixels SPRij, SPGij, and SPBij included in the light-emitting pixel EPij may be connected to the scan line SLi in the i^{th} pixel row to be supplied with the same scan signal, and may be supplied with separate data signals from data lines DLj_R, DLj_G, and DLj_B in the j^{th} pixel column, respectively.

Operations of pixel circuits PC_R, PC_G, and PC_B of the respective sub-light-emitting pixels SPRij, SPGij, and SPBij may be activated according to the scan signal transmitted from the scan line SLi, and driving currents generated by the pixel circuits PC_R, PC_G, and PC_B in response to a data signal may be transmitted to respective light-emitting devices PE_R, PE_G, and PE_B so that an image may be displayed while light having corresponding luminance is emitted.

A dummy pixel DPj may be connected to a dummy scan line DSL and may be insulated from the data line DLj in the j^{th} pixel column. The dummy scan line DSL may be a scan line SL0 in a 0^{th} pixel row or a scan line SLn+1 in an n^{th}+1 pixel row. The dummy pixel DPj may include a dummy pixel circuit DPC and a dummy light-emitting device DPE. The dummy light-emitting device DPE may function as a circuit device without actually emitting light. For example, a light-emitting device may function as a capacitor. The dummy pixel DPj may include a plurality of driver transistors corresponding to the sub-light-emitting pixels SPRij, SPGij, and SPBij included in the light-emitting pixel EPij.

Referring to FIG. 5, one of a plurality of sub-light-emitting pixels SPRij, SPGij, and SPBij included in a light-emitting pixel EPij may be selectively connected to a dummy pixel DPj through a repair line RLj based on any of the a plurality of sub-light-emitting pixels SPRij, SPGij, and SPBij being defective. For example, in the case where the blue sub-light-emitting pixel SPBij is a defective pixel due to a defect in a pixel circuit PC_B, a pixel circuit PC_B and a light-emitting device PE_B of the blue sub-light-emitting pixel SPBij may be separated from each other by cutting, and the light-emitting device PE_B may be connected to the repair line RLj by laser shot. The dummy pixel circuit DPC of the dummy pixel DPj may be connected to each of a blue data line DLj_B and the repair line RLj by laser short. The repair line RLj may be separated from a first power source by cutting. In some embodiments, the dummy pixel circuit DPC may be implemented so that only a driver transistor corresponding to the blue sub-light-emitting pixel SPBij may operate.

Accordingly, a driving current according to a data signal corresponding to the defective blue sub-light-emitting pixel SPBij may be transmitted from the dummy pixel circuit DPC of the dummy pixel DPj to the light-emitting device PE_B of the blue sub-light-emitting pixel SPBij through the repair line RLj. Therefore, the defective blue sub-light-emitting pixel SPBij may be repaired as a normal pixel to generate light having normal luminance.

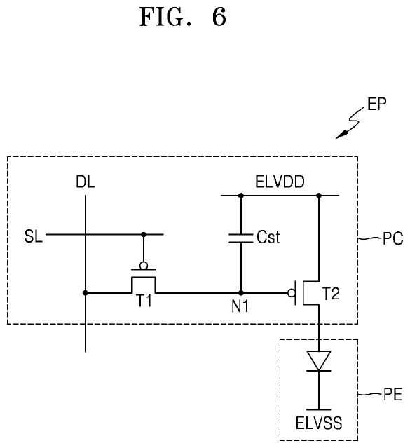

FIG. 6 is a circuit diagram of a light-emitting pixel according to an embodiment.

Referring to FIG. 6, a light-emitting pixel EP may include a light-emitting device PE and a light-emitting pixel circuit PC for supplying a current to the light-emitting device PE. The light-emitting device PE may be an organic light-emitting diode (OLED) including a first electrode, a second electrode facing the first electrode, and a light-emitting layer between the first electrode and the second electrode. The first electrode and the second electrode may be an anode electrode and a cathode electrode, respectively. The light-emitting pixel circuit PC may include two transistors T1 and T2 and one capacitor Cst.

The first transistor T1 may include a gate electrode connected to a scan line, a first electrode connected to a data line, and a second electrode connected to a first node N1.

The second transistor T2 may include a gate electrode connected to the first node N1, a first electrode that receives a first power voltage ELVDD from a first power source, and a second electrode connected to a pixel electrode of the light-emitting element PE.

The capacitor Cst may include a first electrode connected to the first node N1 and a second electrode that receives the first power voltage ELVDD from the first power source.

When a scan signal is supplied from a scan line SL, the first transistor T1 may transmit a data signal supplied from a data line DL to the first electrode of the capacitor Cst. Accordingly, the capacitor Cst may be charged with a voltage corresponding to the data signal, and a driving current corresponding to the voltage charged in the capacitor Cst may be transmitted to the light-emitting device PE through the second transistor T2, so that the light-emitting device PE may emit light.

FIG. 6 illustrates a 2Tr-1Cap structure including two transistors and one capacitor in one pixel, but embodiments are not limited thereto. Therefore, one pixel may include two or more thin film transistors and one or more capacitors and may have various structures by further forming a separate line or omitting an existing wire.

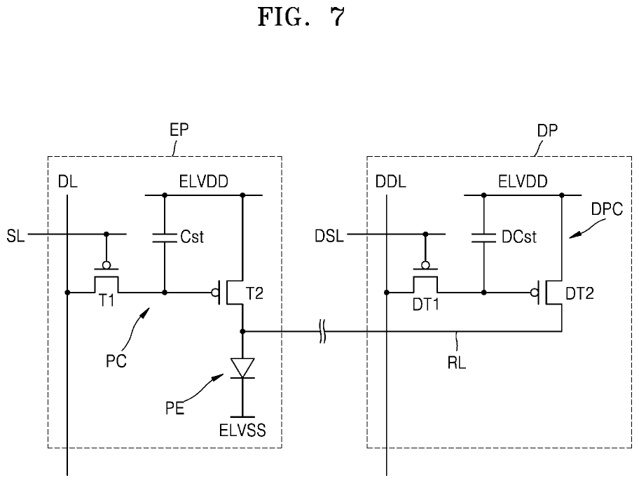

FIG. 7 is a circuit diagram illustrating a light-emitting pixel and a dummy pixel according to an embodiment.

Referring to FIG. 7, a light-emitting pixel EP may include a light-emitting device PE and a light-emitting pixel circuit PC for supplying a current to the light-emitting device PE. The light-emitting pixel EP of FIG. 7 may be the same as the light-emitting pixel EP of FIG. 6. Therefore, even in the case where the above description of the light-emitting pixel EP illustrated in FIG. 6 is omitted below, the above description may be equally applied to the light-emitting pixel EP illustrated in FIG. 7.

A dummy pixel DP may be arranged in the same column or the same row as the light-emitting pixel EP and may include only a dummy pixel circuit DPC. However, the dummy pixel DP may also include a light-emitting device according to the design of the embodiment. The dummy pixel circuit DPC may be the same as the light-emitting pixel circuit PC.

The dummy pixel circuit DPC may include a first dummy transistor DT1 connected to a dummy scan line DSL and a dummy data line DDL, a second dummy transistor DT2 connected between a first power voltage ELVDD and the first dummy transistor DT1, and a dummy capacitor DCst connected between the first power voltage ELVDD and the first dummy transistor DT1. FIG. 7 illustrates an example of the dummy pixel circuit DPC, and the dummy pixel circuit DPC is not limited thereto, and may include one or more thin film transistors and capacitors, or may be formed to have various structures such as omitting a capacitor.

The dummy scan line DSL may be a scan line that is the same as or separate from a scan line SL arranged in the light-emitting pixel circuit PC, and the dummy data line DDL may be a data line that is the same as or separate from a data line DL arranged in the light-emitting pixel circuit PC.

In the case where the light-emitting pixel circuit PC is defective, the light-emitting pixel circuit PC and the light-emitting device PE may be separated from each other. The light-emitting device PE may be connected to the dummy pixel circuit DPC in the same column or the same row through a repair line RL. Accordingly, the light-emitting device PE of the light-emitting pixel EP may be supplied with a driving current from the dummy pixel circuit DPC and normally emit light. Separation and connection between devices may be performed by cutting using a laser and a welding process using a laser, but are not limited thereto.

Embodiments are not limited to the particular pixel structure described above, and may be applied to various pixels to repair a bright spot or a dark spot of a defective pixel due to a defect in a pixel circuit and thus enable light emission without loss of luminance.

FIG. 8 is a circuit diagram illustrating a light-emitting pixel and a dummy pixel according to an embodiment.

Referring to FIG. 8, a light-emitting pixel EP may include a pixel circuit PC connected to a light-emitting diode (LED) or an OLED as a display element. The pixel circuit PC may include a first transistor T1, a second transistor T2, a third transistor T3, a fourth transistor T4, a fifth transistor T5, a sixth transistor T6, a storage capacitor Cst, and a hold capacitor Chd. The first transistor T1 may be a driver transistor outputting a driving current corresponding to a data signal, and the second, third, fourth, fifth, and sixth transistors T2, T3, T4, T5, and T6 may be switching transistors transmitting a signal. Each of the first, second, third, fourth, fifth, and sixth transistors T1, T2, T3, T4, T5, and T6 may include a first terminal (a first electrode) that may be a source or a drain and a second terminal (a second electrode) that may be a terminal different from the first terminal. For example, in the case where the first terminal is a drain, the second terminal may be a source.

The pixel circuit PC may be connected to a first scan line GWL transmitting a scan signal GW, an initialization gate line GIL transmitting an initialization signal GI, a reference gate line GRL transmitting a reference signal GR, a first light-emitting control line EML transmitting a first light-emitting control signal EM, a second light-emitting control line EMBL transmitting a second light-emitting control signal EMB, and a data line DL transmitting a data signal DATA. The pixel circuit PC may be connected to a driving voltage line PL transmitting a driving voltage ELVDD, a first voltage line VL1 transmitting a first reference voltage Vref1, a second voltage line VL2 transmitting a second reference voltage Vref2, and a third voltage line VL3 transmitting an initialization voltage Vint.

The first transistor T1 may be connected between the driving voltage line PL and a second node N2. The first transistor T1 may include a gate, a first terminal, and a second terminal connected to the second node N2. The second terminal may be a source. The first terminal of the first transistor T1 may be connected to the driving voltage line PL via the fifth transistor T5, and the second terminal of the first transistor T1 may be connected to a pixel electrode of the OLED. The first transistor T1 may receive the data signal DATA according to a switching operation of the second transistor T2 and control an amount of a driving current flowing to the OLED.

The second transistor T2 may be connected between the data line DL and a first node N1. The second transistor T2 may include a gate connected to the scan line GWL, a first terminal connected to the data line DL, and a second terminal connected to the first node N1. The second transistor T2 may be turned on by the scan signal GW transmitted to the scan line GWL to electrically connect the data line DL and the first node N1 to each other, and may transmit the data signal DATA transmitted to the data line DL to the first node N1.

The third transistor T3 may be connected between the first node N1 and the first voltage line VL1. The third transistor T3 may include a gate connected to the reference gate line GRL, a first terminal connected to the first node N1, and a second terminal connected to the first voltage line VL1. The third transistor T3 may be turned on by the reference signal GR transmitted to the reference gate line GRL to transmit the reference voltage Vref transmitted to the first voltage line VL1 to the first node N1.

The fourth transistor T4 may be connected between the first transistor T1 and the third voltage line VL3. The fourth transistor T4 may include a gate connected to the initialization gate line GIL, a first terminal connected to a second terminal of the sixth transistor T6 and the OLED, and a second terminal connected to the third voltage line VL3. The fourth transistor T4 may be turned on by the initialization signal GI transmitted to the initialization gate line GIL to transmit the initialization voltage Vint transmitted to the third voltage line VL3 to the pixel electrode of the OLED.

The fifth transistor T5 may be connected between the driving voltage line PL and the first transistor T1. The fifth transistor T5 may include a gate connected to the first light-emitting control line EML, a first terminal connected to the driving voltage line PL, and a second terminal connected to the first terminal of the first transistor T1. The fifth transistor T5 may be turned on or turned off according to the first light-emitting control signal EM transmitted to the first light-emitting control line EML.

The sixth transistor T6 may be connected between the first transistor T1 and the OLED. The sixth transistor T6 may include a gate connected to the second light-emitting control line EMBL, a first terminal connected to the second node N2, and the second terminal connected to the OLED. The sixth transistor T6 may be turned on by the second light-emitting control signal EMB transmitted to the second light-emitting control line EMBL to connect the second node N2 and the pixel electrode of the OLED to each other.

FIG. 8 illustrates that the fifth transistor T5 and the sixth transistor T6 may operate in response to different light-emitting control signals (e.g., the first light-emitting control signal EM and the second light-emitting control signal EMB), respectively, but in some embodiments, the fifth transistor T5 and the sixth transistor T6 may also operate in response to the same light-emitting control signal.

In an embodiment, the reference signal GR may be substantially synchronized with the scan signal GW of the pixel circuit PC located in a previous row. The initialization signal GI may be substantially synchronized with the scan signal GW. In an embodiment, the initialization signal GI may be substantially synchronized with the scan signal GW or the reference signal GR of the pixel circuit PC located in a next row.

The storage capacitor Cst may be connected between the first node N1 and the second node N2. In some embodiments, the pixel circuit PC included in a display apparatus according to an embodiment may be a source follower type circuit in which the storage capacitor Cst is connected between the first node N1 and the second node N2. The storage capacitor Cst may include a first storage electrode CEs1 connected to the first node N1 and a second storage electrode CEs2 connected to the second node N2. The storage capacitor Cst may store a threshold voltage of the first transistor T1 and a voltage corresponding to the data signal DATA.

The hold capacitor Chd may be connected between the second voltage line VL2 and the second node N2. The hold capacitor Chd may include a first hold electrode CEh1 connected to the second voltage line VL2 and a second hold electrode CEh2 connected to the second node N2.

The OLED may include the pixel electrode connected to the second node N2 and a counter electrode facing the pixel electrode, and the counter electrode may be supplied with a common voltage ELVSS. The counter electrode may be a common electrode that is common to a plurality of pixels.

Although FIG. 8 illustrates that the pixel circuit PC includes six transistors and two capacitors, in an embodiment, the pixel circuit PC may include five transistors and two capacitors. In an embodiment, the pixel circuit PC may include seven transistors and two capacitors.

Referring to FIG. 8, a dummy pixel DP may include a dummy pixel circuit DPC. The dummy pixel circuit DPC may include a first transistor T1, a second transistor T2, a third transistor T3, a fourth transistor T4, a fifth transistor T5, a sixth transistor T6, and capacitors Cst and Chd. According to an embodiment, the dummy pixel circuit DPC may be the same as the light-emitting pixel circuit PC of the light-emitting pixel EP. Therefore, although the above description of the dummy pixel DP illustrated in FIG. 8 is omitted below, the above description may be equally applied to the dummy pixel DP illustrated in FIG. 8.

The dummy pixel DP may be arranged in the same column or the same row as the light-emitting pixel EP and may include only the dummy pixel circuit DPC. In some embodiments, unlike the light-emitting pixel EP, the dummy pixel DP may not include the light-emitting device PE. For example, the dummy pixel DP may not be connected to an LED or an OLED as a display element.

However, the dummy pixel DP may also include a light-emitting device according to the design of the embodiment. The dummy pixel circuit DPC may be the same as the light-emitting pixel circuit PC.

The dummy pixel circuit DPC and the light-emitting pixel circuit PC may be connected to each other through a repair line RL. In the case where the light-emitting pixel circuit PC is defective, the light-emitting pixel circuit PC and the light-emitting device PE may be separated from each other. The light-emitting element PE may be connected to the dummy pixel circuit DPC in the same column or the same row through the repair line RL. Accordingly, the light-emitting device PE of the light-emitting pixel EP may be supplied with a driving current from the dummy pixel circuit DPC and normally emit light. Separation and connection between devices may be performed by cutting using a laser and a welding process using a laser, but are not limited thereto.

In some embodiments, a defect may occur in a display panel during a process of manufacturing a flat panel display apparatus such as an OLED. The presence and location of a defect in a display panel described above may be identified by an inspector with the naked eye. However, in the case where the inspector inspects the display panel with the naked eye, an inspection time may be determined according to the condition of the inspector, and inspection criteria may be different for respective inspectors and thus the quality of the display panel may not be maintained uniformly. Visual inspection may take a long time to inspect. Accordingly, an optical inspection method may be used to automatically inspect the display panel.

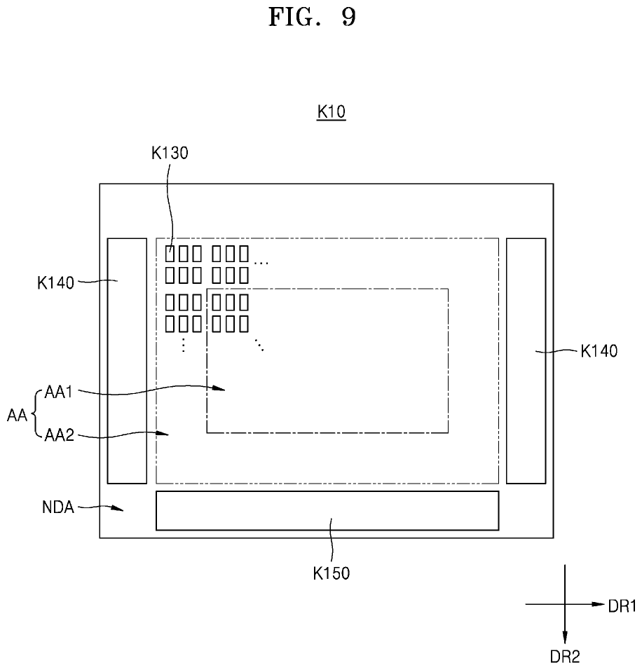

FIG. 9 is a diagram illustrating a display panel inspected by an optical inspection method for a display panel.

Referring to FIG. 9, a display panel K10 may include a display area AA and a peripheral area NDA adjacent to the display area AA. In embodiments, the display area AA may be located in the center of the display panel K10, and the peripheral area NDA may surround the display area AA. For example, the display panel K10 may be a panel for an organic light-emitting display apparatus or a panel for a liquid crystal display apparatus.

Pixels K130 may be arranged in the display area AA. For example, the pixels K130 may be arranged in a first direction and a second direction substantially orthogonal to the first direction. An image, which is a collection of rays of light emitted from the pixels K130, may be displayed in the display area AA. The display area AA may be divided into a central area AA1 located in the center of the display area AA and an edge area AA2 surrounding the central area AA1.

A driver K140, a fan-out unit K150, and the like for driving the pixels K130 may be arranged in the peripheral area NDA. For example, the driver K140 may be arranged in an area adjacent to the display area AA in the first direction and/or in the direction opposite to the first direction, from among the peripheral area NDA, and the fan-out unit K150 may be arranged in an area adjacent to the display area AA in the second direction, from among the peripheral area NDA.

In a process of manufacturing the display panel K10, a patterning process of depositing, etching, and cleaning thin films such as an insulating film and a conductive film arranged on a substrate may be performed. In some embodiments, in the patterning process, a defect may occur in the display panel K10. In the process of manufacturing the display panel K10, foreign substances may flow into the display panel K10 from the outside and thus cause a defect in the display panel K10.

To detect the defect in the display panel K10, an inspection process may be performed during the process of manufacturing the display panel K10 or after manufacturing of the display panel K10 is completed. For example, an optical inspection method of irradiating light onto the display panel K10 and inspecting the display panel K10 by using reflected light may be performed as the inspection process. In particular, in the case where an automatic optical inspection (AOI) method is performed, the defect in the display panel K10 may be automatically identified.

The AOI method may refer to a process of reflecting light from an inspection object by using an optical camera and a light source system to inspect the presence or absence of a defect by using a difference in an amount of reflected light and may refer to an inspection method of comparing repeated patterns and in the case where a different pattern is present, determining the different pattern as defective.

In some embodiments, in an optical inspection method for a display panel, an image may be acquired by capturing the display panel, and unit patterns arranged periodically may be extracted from the acquired image. The unit patterns may be respectively compared with unit patterns adjacent thereto. Whether or not a defect is present in each of the unit patterns may be determined, and in the case where the defect is present in each of the unit patterns, location information of the defect may be acquired.

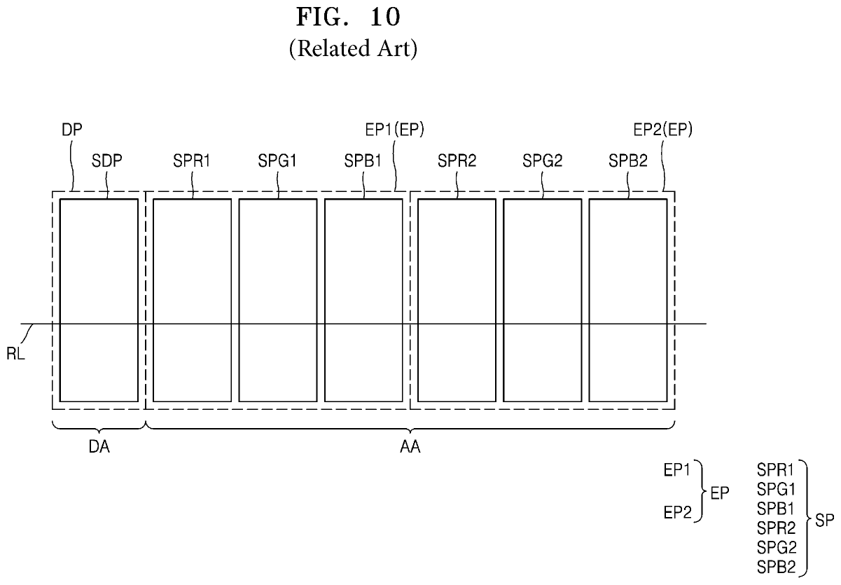

For example, from among pixel patterns included in the unit patterns, pixel patterns corresponding to each other may be compared. For example, as illustrated in FIG. 10 described below, the unit patterns may include three pixel patterns, in one row and in three pixel columns. In some embodiments, pixel patterns corresponding to each other, which are present at the same locations within respective unit patterns, may be compared.

In the optical inspection method for the display panel described above, the unit patterns may be respectively compared with unit patterns surrounding the unit patterns. For example, each of the unit patterns may be compared with eight unit patterns surrounding the corresponding unit pattern.

However, unit patterns located in an area corresponding to the edge area AA2 of the display panel 10K may be adjacent to an area corresponding to the peripheral area NDA of the display panel 10K, in which unit patterns are not arranged. In the case where one unit pattern located in an area corresponding to the edge area AA2 of the display panel 10K is compared with eight unit patterns surrounding the one unit pattern, the one unit pattern may be compared with an area corresponding to the peripheral area NDA of the display panel 10K, in which unit patterns are not arranged, to determine that the one unit pattern has a defect even in the case where the one unit pattern does not have a defect.

Accordingly, the area corresponding to the edge area AA2 of the display panel 10K may be excluded from an inspection area. However, due to this, the inspection area of the display panel 10K may be reduced, and a defect in the edge area AA2 of the display panel 10K may not be found even by an optical inspection process.

As illustrated in FIG. 10, in the case where dummy areas DA are formed on the left and right sides around the display area AA and the dummy area DA on each of the left and right sides includes only one sub-dummy pixel SDP per pixel row, a dummy pixel DP may not constitute the same unit pattern as a unit pattern in the display area AA and thus the occurrence of a defect may not be easy to be detected through the AOI method described above.

Therefore, according to a conventional display apparatus, whether or not a defect occurs in a dummy pixel provided for repair may not be easy to be detected in advance during a process.

To solve the above issue, a display apparatus according to an embodiment may include a dummy pixel unit in which the same pattern as a unit pattern constituted by a light-emitting pixel in a display area may be repeated.

Hereinafter, a display apparatus according to a comparative embodiment and a display apparatus according to an embodiment are compared and described.

FIG. 10 is a diagram schematically illustrating a light-emitting pixel EP and a dummy pixel DP according to a comparative example.

FIG. 10 is a diagram schematically illustrating a display area AA and a portion of a left dummy area DA in the case where dummy areas DA are formed in left and right areas of the display area AA. For convenience of description, FIG. 10 illustrates a light-emitting pixel EP and a dummy pixel DP corresponding to one pixel row.

Referring to FIG. 10, the display apparatus according to the comparative example may include the light-emitting pixel EP including three sub-light-emitting pixels SP. The light-emitting pixel EP may include a red sub-light-emitting pixel, a green sub-light-emitting pixel, and a blue sub-light-emitting pixel. For example, a first light-emitting pixel EP1 may include a red sub-light-emitting pixel SPR1, a green sub-light-emitting pixel SPG1, and a blue sub-light-emitting pixel SPB1 from the left in FIG. 10, and a second light-emitting pixel EP2 may include a red sub-light-emitting pixel SPR2, a green sub-light-emitting pixel SPG2, and a blue sub-light-emitting pixel SPB2 from the left in FIG. 10.

Here, the first light-emitting pixel EP1 and the second light-emitting pixel EP2 may be described as light-emitting pixel units, respectively. In other words, each of the first light-emitting pixel EP1 and the second light-emitting pixel EP2 may be defined as one unit according to a repeated period of the sub-light-emitting pixel SP arranged in the display area AA, and the respective units may be compared with each other.

As described above, the first light-emitting pixel EP1 and the second light-emitting pixel EP2 may form repeated unit patterns. However, the dummy pixel DP may include only one sub-dummy pixel SDP and thus may not constitute the same pattern as the first light-emitting pixel EP1 or the second light-emitting pixel EP2.

Therefore, when the AOI method is used as described above, the dummy pixel DP in the dummy area DA may not be inspected.

The display apparatus according to an embodiment may include the dummy pixel DP that may constitute a unit corresponding to a pattern of the light-emitting pixel EP.

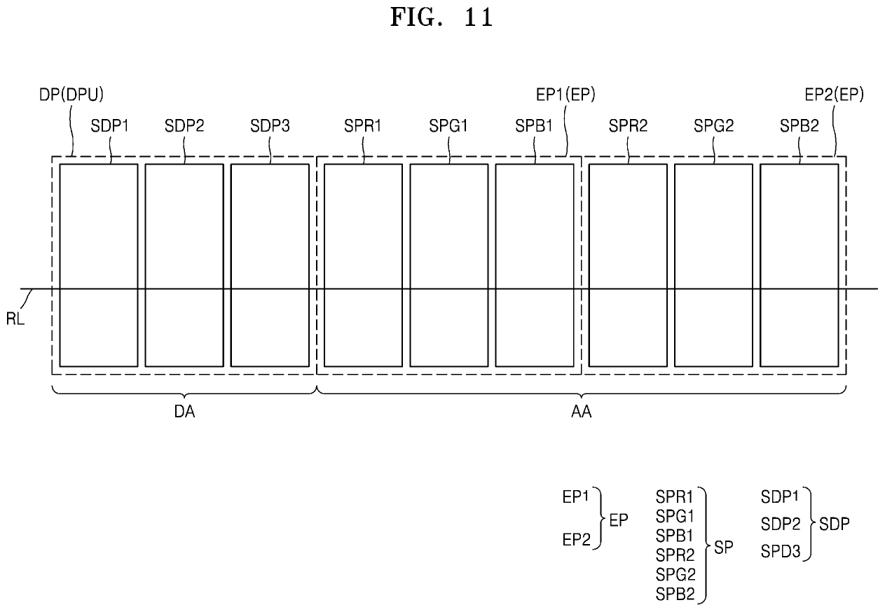

FIG. 11 is a diagram schematically illustrating some light-emitting pixels EP and dummy pixels DP1 of a display apparatus according to an embodiment.

FIG. 11 is a diagram schematically illustrating a display area AA and a portion of a left dummy area DA in the case where dummy areas DA are formed in left and right areas of the display area AA. For convenience of description, FIG. 11 illustrates a light-emitting pixel EP and a dummy pixel DP corresponding to one pixel row.

Referring to FIG. 11, a display apparatus according to an embodiment may include the light-emitting pixel EP including three sub-light-emitting pixels SP. In detail, the light-emitting pixel EP may include a red sub-light-emitting pixel, a green sub-light-emitting pixel, and a blue sub-light-emitting pixel. For example, a first light-emitting pixel EP1 may include a red sub-light-emitting pixel SPR1, a green sub-light-emitting pixel SPG1, and a blue sub-light-emitting pixel SPB1 from the left in FIG. 11, and a second light-emitting pixel EP2 may include a red sub-light-emitting pixel SPR2, a green sub-light-emitting pixel SPG2, and a blue sub-light-emitting pixel SPB2 from the left FIG. 11.

Each of the first light-emitting pixel EP1 and the second light-emitting pixel EP2 may be described as a light-emitting pixel unit. Each of the first light-emitting pixel EP1 and the second light-emitting pixel EP2 may be defined as one unit according to a repeated period of the sub-light-emitting pixel SP arranged in the display area AA and compared with each unit. However, the arrangement order of a red sub-light-emitting pixel, a green sub-light-emitting pixel, and a blue sub-light-emitting is not limited thereto, and sizes and arrangements of areas respectively occupied by the red sub-light-emitting pixel, the green sub-light-emitting pixel, and the blue sub-light-emitting may vary. For convenience of description, the light-emitting pixel EP arranged in order of the red sub-light-emitting pixel, the green sub-light-emitting pixel, and the blue sub-light-emitting pixel is described as an example.

As described above, the first light-emitting pixel EP1 and the second light-emitting pixel EP2 may form repeated unit patterns.

In some embodiments, the dummy pixel DP may include a first sub-dummy pixel SDP1, a second sub-dummy pixel SDP2, and a third sub-dummy pixel SDP3. In some embodiments, the first sub-dummy pixel SDP1, the second sub-dummy pixel SDP2, and the third sub-dummy pixel SDP3 may be sub-dummy pixels SDP respectively corresponding to a red sub-light-emitting pixel, a green sub-light-emitting pixel, and a blue sub-light-emitting pixel of the light-emitting pixel EP.

In some embodiments, the dummy pixel DP may be defined as a dummy pixel unit DPU having a pattern such as patterns repeated in the first light-emitting pixel EP1 and the second light-emitting pixel EP2.

As described above, the dummy pixel DP in the dummy area DA may also have the same unit pattern as the light-emitting pixel EP in the display area AA, and thus, an inspection area may extend to the dummy pixel DP.

According to an embodiment, whether or not a defect occurs in the dummy pixel DP may be identified by using the AOI method described above.

In some embodiments, any one of the first sub-dummy pixel SDP1, the second sub-dummy pixel SDP2, and the third sub-dummy pixel SDP3 of the dummy pixel DP may be a sub-dummy pixel for repair, which is used in a repair process of the light-emitting pixel EP, and the others may be auxiliary sub-dummy pixels provided for AOI. That is, the sub-dummy pixel that is used to repair a defective sub-pixel may be the repair sub-dummy pixel, and since the repair line is used to connect this repair sub-dummy pixel to a corresponding light-emitting device of the defective sub-pixel (or its own light-emitting device in some embodiments), and the remaining sub-dummy pixels become auxiliary sub-dummy pixels configured to be used to perform the AOI.

A dummy pixel circuit DPC of the sub-dummy pixel for repair may be used as a replacement for a light-emitting pixel circuit PC of the light-emitting pixel EP.

In some embodiments, one of a plurality of sub-dummy pixels SDP may be designed to be driven by the dummy pixel circuit DPC.

Driving of the remaining sub-dummy pixels SDP except for the sub-dummy pixel for repair may be limited. That is, after being repaired, the repair sub-dummy pixel may be driven, and the remaining sub-dummy pixels may not be driven (e.g., may not receive a signal) or may receive a constant low signal that does not cause the remaining sub-dummy pixels to operate as a sub-pixel. An auxiliary sub-dummy pixel may be provided for AOI and thus may not be used in an actual repair process. In some embodiments, an additional sub-dummy pixel SDP excluding the sub-dummy pixel for repair may be a component for forming a repeated pattern so that the dummy pixel DP may be a target for AOI.

In some embodiments, FIG. 11 illustrates only the left dummy area DA, but a dummy pixel DP including a plurality of sub-dummy pixels SDP may be provided in a dummy area on the right side of the display area AA.

Hereinafter, a display apparatus according to an embodiment is described. The display apparatus according to the embodiment may include the dummy pixel DP in the dummy area DA that characteristically varies compared to the display apparatus of the embodiment described with reference to FIG. 11. Hereinafter, components which are different from components of the embodiments described above are described in detail.

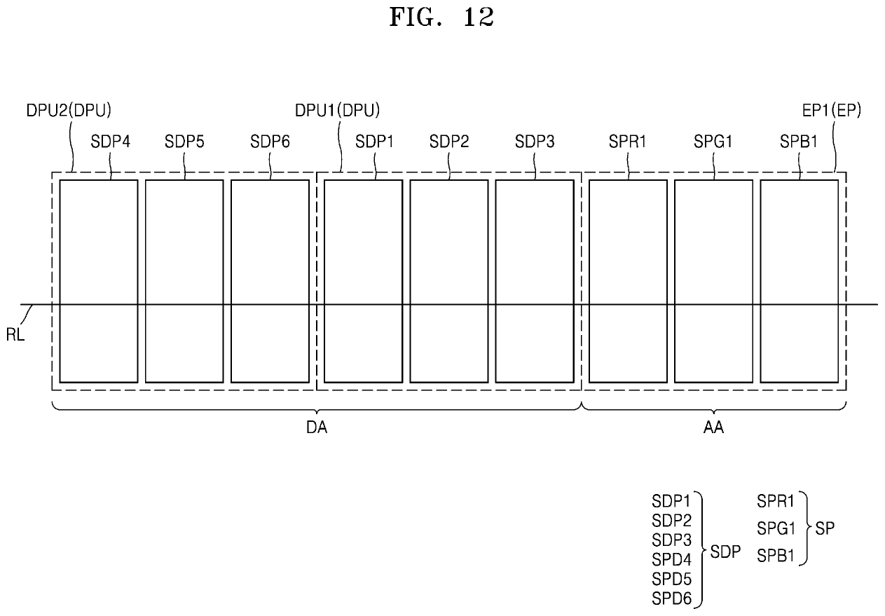

FIG. 12 is a diagram schematically illustrating a portion of a light-emitting pixel EP and a dummy pixel DP of a display apparatus, according to an embodiment.

Referring to FIG. 12, a display apparatus according to an embodiment may include a light-emitting pixel EP including three sub-light-emitting pixels SP. In some embodiments, the light-emitting pixel EP may include a red sub-light-emitting pixel, a green sub-light-emitting pixel, and a blue sub-light-emitting pixel. For example, a first light-emitting pixel EP1 may include a red sub-light-emitting pixel SPR1, a green sub-light-emitting pixel SPG1, and a blue sub-light-emitting pixel SPB1 from the left in FIG. 12.

For convenience of description, FIG. 12 illustrates the light-emitting pixel EP and the dummy pixel DP corresponding to one pixel row, but the embodiment is not limited thereto, and dozens or hundreds of pixel rows or pixel columns may be arranged in a display area AA, and corresponding to the same, the dummy pixel DP may be repeatedly formed in a row direction or a column direction in each pixel row unit or each pixel column unit.

Referring to FIG. 12, unit patterns repeated in a display area AA may be equally repeated in the dummy pixel DP. In some embodiments, a plurality of dummy pixel units DPU corresponding to the light-emitting pixel EP may be provided.

From among the plurality of dummy pixel units DPU, a first dummy pixel unit DPU1 may be adjacent to a boundary of the display area AA, and a second dummy pixel unit DPU2 may be adjacent to a first dummy pixel unit DPU1.

As in the embodiment described above, the first dummy pixel unit DPU1 may include a first sub-dummy pixel SDP1, a second sub-dummy pixel SDP2, and a third sub-dummy pixel SDP3. In some embodiments, the first sub-dummy pixel SDP1, the second sub-dummy pixel SDP2, and the third sub-dummy pixel SDP3 may refer to sub-dummy pixels SDP respectively corresponding to a red sub-light-emitting pixel SPR1, a green sub-light-emitting pixel SPG1, and a blue sub-light-emitting pixel SPB1 of a first light-emitting pixel EP1.

In some embodiments, the first dummy pixel unit DPU1 may be defined as the dummy pixel unit DPU having the same pattern as a pattern of the first light-emitting pixel EP1.

The second dummy pixel unit DPU2 may include a fourth sub-dummy pixel SDP4, a fifth sub-dummy pixel SDP5, and a sixth sub-dummy pixel SDP6. In some embodiments, the fourth sub-dummy pixel SDP4, the fifth sub-dummy pixel SDP5, and the sixth sub-dummy pixel SDP6 may refer to sub-dummy pixels SDP respectively corresponding to the red sub-light-emitting pixel SPR1, the green sub-light-emitting pixel SPG1, and the blue sub-light-emitting pixel SPB1 of the first light-emitting pixel EP1.

For example, the second dummy pixel unit DPU2 may be defined as a dummy pixel unit DPU having the same pattern as the pattern of the first light-emitting pixel EP1.

In the case where only the first dummy pixel unit DPU1 is present, a left end of the first sub-dummy pixel SDP1 may have a pattern difference from a left end of the light-emitting pixel EP, and thus, an inspection error may occur due to the pattern difference. However, the second dummy pixel unit DPU2 may be arranged adjacent to the first dummy pixel unit DPU1, and thus, the left end of the first sub-dummy pixel SDP1 may be connected to a right end of the sixth sub-dummy pixel SDP6 and may form substantially the same pattern as a repeated pattern of the light-emitting pixel EP.

Accordingly, the display apparatus according to the embodiment may reduce an inspection error that may occur at the left end of the first dummy pixel unit DPU1.

As described above, the dummy pixel DP in a dummy area DA may also have the same unit pattern as the light-emitting pixel EP in the display area AA, and thus, an inspection area may extend to the dummy pixel DP.

According to an embodiment, the AOI method described above used to identify whether or not a defect occurs in the dummy pixel DP.

In some embodiments, any one of the first sub-dummy pixel SDP1, the second sub-dummy pixel SDP2, the third sub-dummy pixel SDP3, the fourth sub-dummy pixel SDP4, the fifth sub-dummy pixel SDP5, and the sixth sub-dummy pixel SDP6 may refer to a sub-dummy pixel for repair, which is used in a repair process for the light-emitting pixel EP, and the others may refer to auxiliary sub-dummy pixels provided for AOI.

In an embodiment, the first dummy pixel unit DPU1 may include a sub-dummy pixel for repair. In some embodiments, the third sub-dummy pixel SDP3 may refer to a sub-dummy pixel for repair. The remaining sub-dummy pixels SDP except for the third sub-dummy pixel SDP3 may refer to auxiliary sub-dummy pixels. However, the disclosure is not necessarily limited thereto, and the dummy pixel DP may include one or more sub-dummy pixels SDP for repair.

In an embodiment, a sub-dummy pixel SDP adjacent to the first sub-dummy pixel SDP1 may be additionally arranged at a left boundary of the first dummy pixel unit DPU1.

To describe the above example from a different viewpoint, the second dummy pixel unit DPU2 may include only one sub-dummy pixel SDP.

The additional sub-dummy pixel SDP may be connected to the left end of the first sub-dummy pixel SDP1, and thus, a pattern difference may not occur at the left end of the first dummy pixel unit DPU1 to reduce an inspection error.

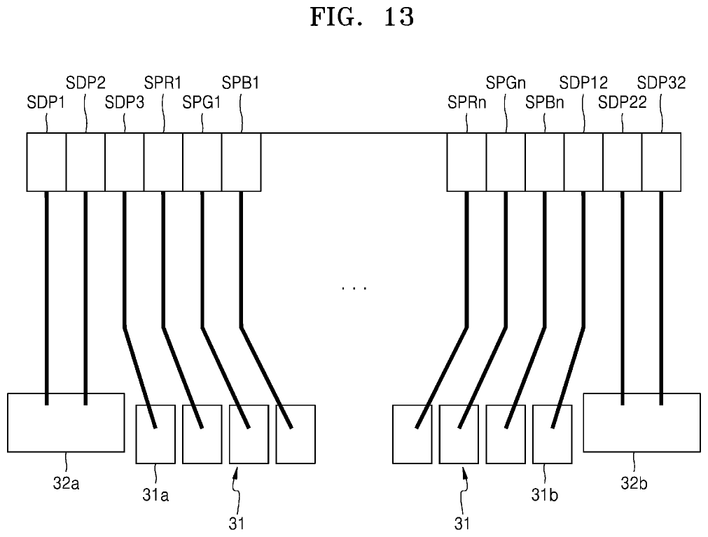

FIG. 13 is a diagram schematically illustrating a line connection between a light-emitting pixel and a dummy pixel below a panel of a display apparatus, according to an embodiment.

The display apparatus may include a driver circuit unit, a voltage supply line, and a pad unit arranged in a peripheral area. The pad unit may include a plurality of pads such as a data pad 31. The pad unit may be exposed without being covered by an insulating layer to be electrically connected to a printed circuit board. The pads of the pad unit may be electrically connected to a terminal unit of the printed circuit board. The printed circuit board may transmit a signal or a voltage of a controller to a display panel.

A sub-light-emitting pixel SP of the light-emitting pixel EP may be connected to the data pad 31 of the pad unit. A data signal (or a data voltage) of a data driver 30 may be provided to each pixel circuit PC through a connection line connected to the data pad 31 and a data line DL connected to the connection line.

In some embodiments, from among sub-dummy pixels SDP of a dummy pixel unit DPU, a sub-dummy pixel for repair may be connected to a data pad through a data line for repair to be provided with a data signal for repair.

In some embodiments, from among the sub-dummy pixels SDP of the dummy pixel unit DPU, an auxiliary sub-dummy pixel may be connected to a voltage supply line through a dummy data line to be provided with a common voltage ELVSS.

In some embodiments, the data signal for repair may be applied only to the sub-dummy pixel SDP used in an actual repair process, and a constant voltage (e.g., ELVSS) may be applied to the auxiliary sub-dummy pixel. Accordingly, the auxiliary sub-dummy pixel may be restricted so that a light-emitting device may not be driven. However, the above description of the auxiliary sub-dummy pixel is an example, and the auxiliary sub-dummy pixel may receive a different signal from the data signal for repair through the dummy data line. In some embodiments, a different signal may be applied to the auxiliary sub-dummy pixel through the dummy data line, and thus, a driving current output of a driver transistor may be limited. For example, in the case where the driver transistor may be turned off when a signal corresponding to a dummy data signal provided through the dummy data line is applied to a gate electrode of the driver transistor, the dummy data signal may refer to a signal provided through the dummy data line.

As shown in FIG. 13, SDP3 is a sub-dummy pixel for repair, and is thus connected to data pad 31a, while SDP12 is a sub-dummy pixel for repair, and is thus connected to data pad 31b, such that SDP3 and SDP12 may function as sub-pixels that replace defective sub-pixels. Based on this connection to the data pads, the remaining sub-dummy pixels are auxiliary sub-dummy pixels that receive power from power from power sources but do not receive data. As shown in FIG. 13, SDP1 and SDP2 are auxiliary sub-dummy pixels connected to power source 32a, and SDP22 and SDP32 are auxiliary sub-dummy pixels connected to power source 32b.

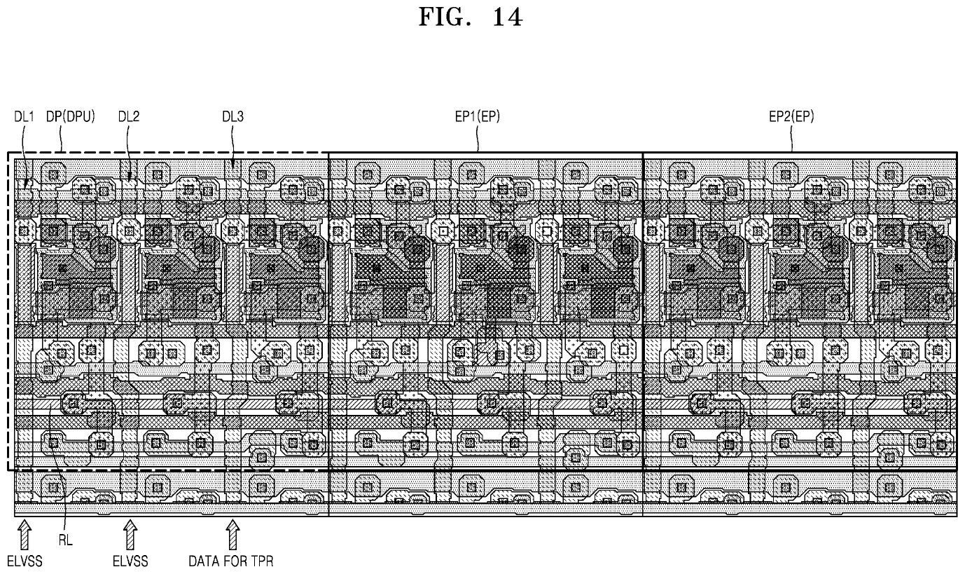

FIG. 14 is a plan view of a pixel array of a display apparatus according to an embodiment, including a pixel circuit of FIG. 8.

FIG. 14 illustrates pixels arranged in the same row of adjacent columns. Pixel circuits of a first light-emitting pixel EP1 arranged in the center and a second light-emitting pixel EP2 arranged in a right area of FIG. 14 may have the same structure. The pixel circuit arranged in each of the first light-emitting pixel EP1 and the second light-emitting pixel EP2 may correspond to the pixel circuit of FIG. 8 described above. A pixel circuit of a dummy pixel DP arranged in a left area may have the same structure as the pixel circuit arranged in the first light-emitting pixel EP1.

The first light-emitting pixel EP1 and the second light-emitting pixel EP2 may refer to unit pixel units including sub-light-emitting pixels SP, and the dummy pixel DP may refer to a dummy pixel unit DPU including a sub-dummy pixel SDP.

The pixel circuits of the dummy pixel DP, the first light-emitting pixel EP1, and the second light-emitting pixel EP2 may include a repair line RL. The repair line RL may be arranged along pixels arranged in the same row. The repair line RL may be insulated from the light-emitting pixel EP and the dummy pixel DP. The repair line RL may be insulated from each of a light-emitting device of the light-emitting pixel EP and a dummy pixel circuit DPC of the dummy pixel DP with an insulating layer therebetween. The repair line RL may be electrically connected to each of the light-emitting device of the light-emitting pixel EP and the dummy pixel circuit DPC of the dummy pixel DP by laser short during later repair.

A common voltage ELVSS may be applied to a first dummy data line DL1 connected to a first sub-dummy pixel and a second dummy data line DL2 connected to a second sub-dummy pixel.

A signal for repair TPR data may be applied to a third dummy data line DL3 connected to a third sub-dummy pixel.

From among the light-emitting pixel EP arranged in a display area AA, the first light-emitting pixel EP1 may form a repeated pattern with the second light-emitting pixel EP2 adjacent to the first light-light emitting pixel EP1, and a dummy pixel unit DPU in a dummy area DA adjacent to the display area AA may form the same pattern as the first light-emitting pixel EP1 or the second light-emitting pixel EP2 at least until a phase in which a light-emitting device is formed.

Referring to FIG. 14, the light-emitting pixel EP and the dummy pixel DP arranged in the same row of adjacent columns may form the same pattern, and thus, during AOI, a pattern of the dummy pixel DP may be compared with a pattern of the light-emitting pixel EP around the dummy pixel DP to determine whether or not a defect occurs. Therefore, according to an embodiment, not only the light-emitting pixel EP but also the dummy pixel DP may be inspected by the AOI method.

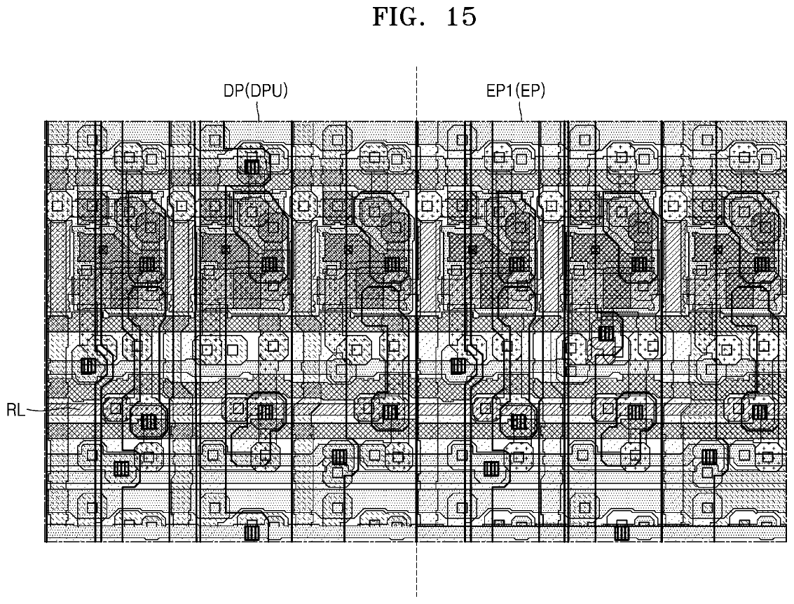

FIG. 15 is a plan view illustrating a pixel array before a light-emitting device is formed in a display apparatus according to an embodiment, including the pixel circuit of FIG. 8.

FIG. 15 illustrates pixels arranged in the same row of adjacent columns. Pixel circuits of a first light-emitting pixel EP1 arranged in a right area and a dummy pixel DP arranged in a left area of FIG. 15 may have the same structure. The pixel circuit arranged in each of the first light-emitting pixel EP1 and the dummy pixel DP may correspond to the pixel circuit of FIG. 8 described above.

A dummy pixel unit DPU in a dummy area DA adjacent to a display area AA may form the same pattern as the first light-emitting pixel EP1 at least until a phase in which a light-emitting device is formed. Although only the first light-emitting pixel EP1 is illustrated herein, the dummy pixel unit DPU may form the same pattern as light-emitting pixels EP arranged in the same row of adjacent columns.

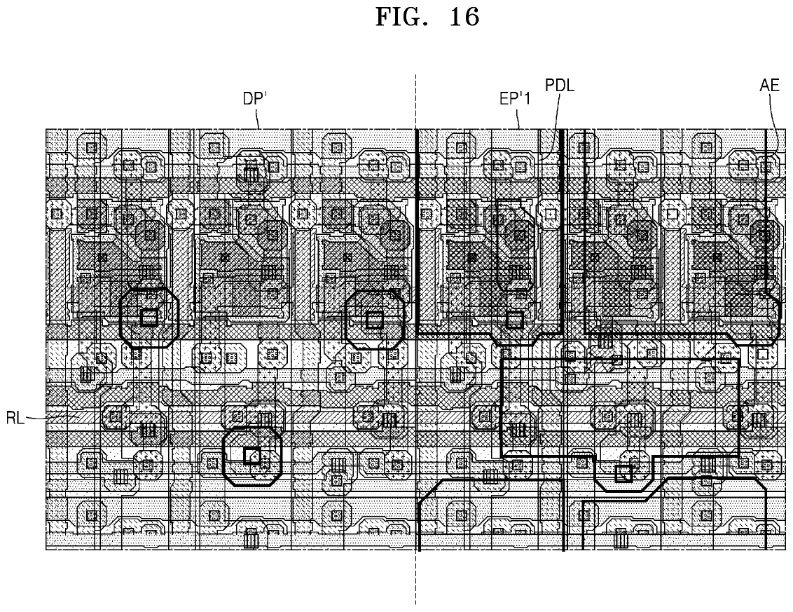

FIG. 16 is a plan view illustrating a pixel array formed from a pixel array of FIG. 15 to a light-emitting device according to an embodiment.

FIG. 16 illustrates pixels arranged in the same row of adjacent columns. A first light-emitting pixel EP′1 arranged in a right area of FIG. 16 may form a pixel electrode AE and a pixel defining layer PDL, but a dummy pixel DP′ arranged in a left area may not form the pixel electrode AE and the pixel defining layer PDL. In some embodiments, the dummy pixel DP′ may not be formed to a light-emitting device. Accordingly, the dummy pixel DP′ in a dummy area DA may not include a light-emitting device, and thus, light emission may be fundamentally blocked.

In the case where a display apparatus is configured as described above, the display apparatus may be inspected for the occurrence of a defect through AOI on a process phase before a light-emitting device formation phase.

In an embodiment, a dummy pixel unit DPU may form the same pattern as a light-emitting pixel in all layers. The dummy pixel unit may include a light-emitting device and may be formed in the same manner as the light-emitting pixel.

To describe the above example from a different viewpoint, a first layer of a dummy pixel unit may have the same pattern as a second layer of a light-emitting pixel, which includes the same material as the first layer.

Therefore, in the case where a display apparatus is configured as described above, the display apparatus may be inspected for the occurrence of a defect through AOI in process phases for all layers.

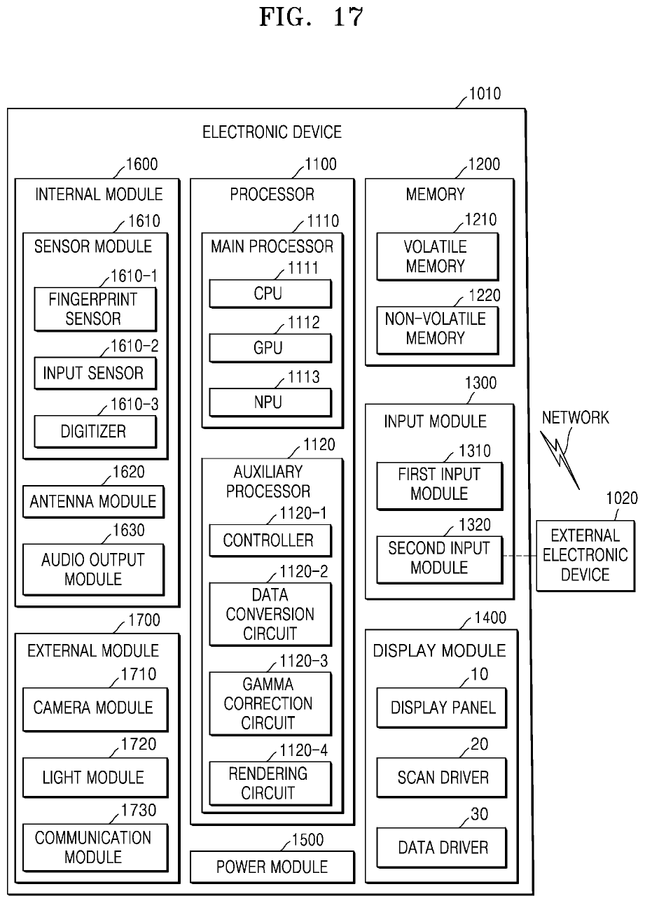

FIG. 17 is a block diagram of an electronic device according to embodiments.

An electronic device 1010 may output, within an operating system, various types of information through a display module 1400. In the case where a processor 1100 executes an application stored in a memory 1200, the display module 1400 may provide application information to a user through a display panel 10.

The processor 1100 may acquire an external input through an input module 1300 or a sensor module 1610 and execute an application corresponding to the external input. For example, in the case where the user selects a camera icon displayed on the display panel 10, the processor 1100 may acquire a user input through an input sensor 1610-2 and activate a camera module 1710. The processor 1100 may transmit, to the display module 1400, image data corresponding to a captured image acquired through the camera module 1710. The display module 1400 may display, through the display panel 10, an image corresponding to the captured image.

In an embodiment, in the case where personal information authentication is performed on the display module 1400, a fingerprint sensor 1610-1 may acquire input fingerprint information as input data. The processor 1100 may compare the input data acquired through the fingerprint sensor 1610-1 with authentication data stored in the memory 1200 and execute an application according to the result of the comparison. The display module 1400 may display, through the display panel 10, information executed according to logic of the application.

In an embodiment, in the case where a music streaming icon displayed on the display module 1400 is selected, the processor 1100 may acquire a user input through an input sensor 1610-2 and activate a music streaming application stored in the memory 1200. In the case where a music execution command is input in the music streaming application, the processor 1100 may activate a sound output module 1630 to provide the user with sound information corresponding to the music execution command.

The operation of the electronic device 1010 is briefly described above. Hereinafter, a structure of the electronic device 1010 is described in detail. Some of components of the electronic device 1010 described below may be integrated and provided as one component, or one component may be separated into two or more components and provided.

Referring to FIG. 17, the electronic device 1010 may communicate with an external electronic device 1020 through a network (e.g., a short-range wireless communication network or a long-range wireless communication network). According to an embodiment, the electronic device 1010 may include the processor 1100, the memory 1200, the input module 1300, the display module 1400, a power module 1500, an internal module 1600, and an external module 1700. According to an embodiment, at least one of the components described above may be omitted from the electronic device 1010, or one or more other components may be added to the electronic device 1010. According to an embodiment, some of the components described above (e.g., the sensor module 1610, an antenna module 1620, or the sound output module 1630) may be integrated into another component (e.g., the display module 1400).

The processor 1100 may execute software to control at least one other component (e.g., a hardware or software component) of the electronic device 1010, which is connected to the processor 1100, and may perform various types of data processing or calculations. According to an embodiment, as at least a portion of data processing or calculations, the processor 1100 may store, in a volatile memory 1210, a command or data received from another component (e.g., the input module 1300, the sensor module 1610, or a communication module 1730), process the command or data stored in the volatile memory 1210, and store result data in a nonvolatile memory 1220.

The processor 1100 may include a main processor 1110 and an auxiliary processor 1120. The main processor 1110 may include one or more of a central processing unit (CPU) 1111 or an application processor (AP). The main processor 1110 may further include one or more of a graphic processing unit (GPU) 1112, a communication processor (CP), and an image signal processor (ISP). The main processor 1110 may further include a neural processing unit (NPU) 1113. The NPU 1113 may refer to a processor specialized in processing an artificial intelligence model, and the artificial intelligence model may be generated through machine learning. The artificial intelligence model may include a plurality of artificial neural network layers. An artificial neural network may refer to one of a deep neural network (DNN), a convolutional neural network (CNN), a recurrent neural network (RNN), a restricted Boltzmann machine (RBM), a deep belief network (DBN), a bidirectional recurrent deep natural network (BRDN), deep Q-networks, and a combination of two or more thereof, but is not limited to the example described above. In addition to a hardware structure, the artificial intelligence model may additionally or alternatively include a software structure. At least two of a processing unit and a processor described above may be implemented as one integrated component (e.g., a single chip) or may be respectively implemented as independent components (e.g., a plurality of chips).

The auxiliary processor 1120 may include a controller 1120-1. The controller 1120-1 may include an interface conversion circuit and a timing control circuit. The controller 1120-1 may receive an image signal from the main processor 1110, convert a data format of the image signal to match an interface specification with the display module 1400, and output image data. The controller 1120-1 may output various types of control signals needed for driving the display module 1400.

The auxiliary processor 1120 may further include the controller 1120-1, a data conversion circuit 1120-2, a gamma correction circuit 1120-3, a rendering circuit 1120-4, and the like. The data conversion circuit 1120-2 may receive image data from the controller 1120-1 and compensate for the image data so that an image is displayed at desired luminance according to characteristics of the electronic device 1010, setting of the user, or the like or convert the image data to reduce power consumption or compensate for an afterimage. The gamma correction circuit 1120-3 may convert the image data, a gamma reference voltage, or the like so that the image displayed on the electronic device 1010 has desired gamma characteristics. The rendering circuit 1120-4 may receive the image data from the controller 1120-1, and render the image data by considering an arrangement of pixels of the display panel 10 and the like, which are applied to the electronic device 1010. At least one of the data conversion circuit 1120-2, the gamma correction circuit 1120-3, and the rendering circuit 1120-4 may be integrated into another component (e.g., the main processor 1110 or the controller 1120-1). At least one of the data conversion circuit 1120-2, the gamma correction circuit 1120-3, and the rendering circuit 1120-4 may be integrated into a data driver 30 described below.

The memory 1200 may store various types of data used by at least one component (e.g., the processor 1100 or the sensor module 1610) of the electronic device 1010, and input data or output data for a command related thereto. The memory 1200 may include at least one of the volatile memory 1210 and the nonvolatile memory 1220.

The input module 1300 may receive a command or data to be used in a component of the electronic device 1010 (e.g., the processor 1100, the sensor module 1610, or the sound output module 1630) from the outside of the electronic device 1010 (e.g., the user or the external electronic device 1020).

The input module 1300 may include a first input module 1310 into which a command or data is input from the user and a second input module 1320 into which a command or data is input from the external electronic device 1020. The first input module 1310 may include a microphone, a mouse, a keyboard, a key (e.g., a button), or a pen (e.g., a passive pen or an active pen). The second input module 1320 may support a designated protocol that may enable a wired or wireless connection to the external electronic device 1020. According to an embodiment, the second input module 1320 may include a high definition multimedia interface (HDMI), a universal serial bus (USB) interface, a secure digital (SD) card interface, or an audio interface. The second input module 1320 may include a connector that may enable a physical connection to the external electronic device 1020, e.g., an HDMI connector, a USB connector, an SD card connector, or an audio connector (e.g., a headphone connector).

The display module 1400 may visually provide information to the user. The display module 1400 may include the display panel 10, a scan driver 20, and the data driver 30. The display module 1400 may further include a window, a chassis, and a bracket for protecting the display panel 10.

The scan driver 20 may refer to a driver chip and may be mounted on the display panel 10. The scan driver 20 may be integrated into the display panel 10. For example, the scan driver 20 may include an amorphous silicon TFT gate driver circuit (ASG), a low temperature polycrystalline silicon (LTPS) TFT gate driver circuit, or an oxide semiconductor TFT gate driver circuit (OSG) embedded in the display panel 10. The scan driver 20 may receive a control signal from the controller 1120-1 and output scan signals to the display panel 10 in response to the control signal.

The display panel 10 may further include a light-emitting driver. The light-emitting driver may output a light-emitting control signal to the display panel 10 in response to the control signal received from the controller 1120-1. The light-emitting driver may be formed separately from the scan driver 20 or may be integrated into the scan driver 20.

The data driver 30 may receive the control signal from the controller 1120-1, convert the image data into analog voltages (e.g., data voltages) in response to the control signal, and then output the data voltages to the display panel 10.

The data driver 30 may be integrated into another component (e.g., the controller 1120-1). Functions of the interface conversion circuit and the timing control circuit of the controller 1120-1 described above may be integrated into the data driver 30.

The display module 1400 may further include the light-emitting driver, a voltage generation circuit, and the like. The voltage generation circuit may output various types of voltages needed for driving the display panel 10.

The power module 1500 may supply power to components of the electronic device 1010. For example, the power module 1500 may generate the first power voltage ELVDD and the second power voltage ELVSS described above. The power module 1500 may generate a gate driving voltage (e.g., a gate high voltage or a gate low voltage) needed for driving the scan driver 20.

For example, the power module 1500 may refer to a power generation unit, a power supply, or the like. For example, the power module 1500 may include a battery that charges a power voltage. The battery may include a non-rechargeable primary battery, a rechargeable secondary battery, or a fuel cell.

For example, the power module 1500 may include a power management integrated circuit (PMIC). The PMIC may supply optimized power to each of the modules described above and modules described below.

For example, the power module 1500 may include a wireless power transceiver electrically connected to the battery. The wireless power transceiver may include a plurality of antenna radiators having a coil shape.

The electronic device 1010 may further include the internal module 1600 and the external module 1700. The internal module 1600 may include the sensor module 1610, an antenna module 1620, and the sound output module 1630. The external module 1700 may include the camera module 1710, a light module 1720, and a communication module 1730.

The sensor module 1610 may detect an input by the body of the user or an input by a pen of the first input module 1310, and generate an electrical signal or a data value corresponding to the input. The sensor module 1610 may include at least one of the fingerprint sensor 1610-1, the input sensor 1610-2, and a digitizer 1610-3.

The fingerprint sensor 1610-1 may generate a data value corresponding to a fingerprint of the user. The fingerprint sensor 1610-1 may include any one of an optical type fingerprint sensor or a capacitive type fingerprint sensor.

The input sensor 1610-2 may generate a data value corresponding to coordinate information of the input by the body of the user or the input by the pen. The input sensor 1610-2 may generate a change in capacitance caused by the input as a data value. The input sensor 1610-2 may detect an input by the passive pen or transmit and receive data to and from the active pen.

The input sensor 1610-2 may also measure a biosignal such as blood pressure, moisture, or body fat. For example, in the case where the user touches a sensor layer or a sensing panel with a body part and does not move for a certain period of time, the input sensor 1610-2 may detect a biosignal and output information desired by the user to the display module 1400, on the basis of a change in an electric field caused by the body part.

The digitizer 1610-3 may generate a data value corresponding to the coordinate information of the input by the pen. The digitizer 1610-3 may generate the amount of a change in electromagnetism caused by an input as a data value. The digitizer 1610-3 may detect the input by the passive pen or transmit and receive data to and from the active pen.

At least one of the fingerprint sensor 1610-1, the input sensor 1610-2, and the digitizer 1610-3 may also be implemented as a sensor layer formed on the display panel 10 through a continuous process. The fingerprint sensor 1610-1, the input sensor 1610-2, and the digitizer 1610-3 may be arranged on an upper side of the display panel 10, and any one of the fingerprint sensor 1610-1, the input sensor 1610-2, and the digitizer 1610-3, e.g., the digitizer 1610-3, may be arranged on a lower side of the display panel 10.

At least two of the fingerprint sensor 1610-1, the input sensor 1610-2, and the digitizer 1610-3 may be integrated into one sensing panel through the same process. In the case where at least two of the fingerprint sensor 1610-1, the input sensor 1610-2, and the digitizer 1610-3 is integrated into one sensing panel, the sensing panel may be arranged between the display panel 10 and a window arranged on the upper side of the display panel 10. According to an embodiment, the sensing panel may be arranged on the window, and a location of the sensing panel is not particularly limited.

At least one of the fingerprint sensor 1610-1, the input sensor 1610-2, and the digitizer 1610-3 may be embedded in the display panel 10. In some embodiments, at least one of the fingerprint sensor 1610-1, the input sensor 1610-2, and the digitizer 1610-3 may be simultaneously formed through a process of forming devices (e.g., a light-emitting device, a transistor, and the like) included in the display panel 10.

The sensor module 1610 may generate an electrical signal or a data value corresponding to an internal state or an external state of the electronic device 1010. The sensor module 1610 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting or receiving a signal or power to or from the outside. According to an embodiment, the communication module 1730 may transmit a signal to the external electronic device 1020 or receive a signal from the external electronic device 1020, through an antenna appropriate for a communication method. An antenna pattern of the antenna module 1620 may be integrated into one component (e.g., the display panel 10) of the display module 1400, the input sensor 1610-2, or the like.

The sound output module 1630 may refer to a device for outputting a sound signal to the outside of the electronic device 1010, and may include, for example, a speaker used for a general purpose, such as multimedia playback or recording playback, and a receiver used exclusively for phone reception. According to an embodiment, the receiver may be formed integrally with or separately from the speaker. A sound output pattern of the sound output module 1630 may be integrated into the display module 1400.

The camera module 1710 may capture a still image and a moving image. According to an embodiment, the camera module 1710 may include one or more lenses, an image sensor, or an image signal processor. The camera module 1710 may further include an infrared camera capable of measuring the presence or absence of the user, a location of the user, the gaze of the user, and the like.

The light module 1720 may provide light. The light module 1720 may include a light-emitting diode or a xenon lamp. The light module 1720 may operate in conjunction with the camera module 1710 or independently.

The communication module 1730 may support establishing a wired or wireless communication channel between the electronic device 1010 and the external electronic device 1020 and performing communication through the established communication channel. The communication module 1730 may include any one or both of a wireless communication module such as a cellular communication module, a short-range wireless communication module, or a global navigation satellite system (GNSS) communication module and a wired communication module such as a local area network (LAN) communication module or a power line communication module. The communication module 1730 may communicate with the external electronic device 1020 through a short-range communication network such as Bluetooth, WiFi direct, or infrared data association (IrDA) or a long-range communication network such as a cellular network, the Internet, or a computer network (e.g., a LAN or a wide area network (WAN)). Various types of communication modules 1730 described above may be implemented as a single chip or may be implemented as separate chips.

The input module 1300, the sensor module 1610, the camera module 1710, and the like may be used to control an operation of the display module 1400 in conjunction with the processor 1100.

The processor 1100 may output a command or data to the display module 1400, the sound output module 1630, the camera module 1710, or the light module 1720, on the basis of the input data received from the input module 1300. For example, the processor 1100 may generate image data in response to input data applied through a mouse, an active pen, or the like and output the image data to the display module 1400, or may generate command data in response to the input data and output the command data to the camera module 1710 or the light module 1720. In the case where input data is not received from the input module 1300 for a certain time, the processor 1100 may reduce power consumed by the electronic device 1010 by switching an operation mode of the electronic device 1010 to a low power mode or a sleep mode.

The processor 1100 may output a command or data to the display module 1400, the sound output module 1630, the camera module 1710, or the light module 1720, on the basis of sensing data received from the sensor module 1610. For example, the processor 1100 may compare authentication data applied by the fingerprint sensor 1610-1 with authentication data stored in the memory 1200, and then execute an application according to the result of the comparison. The processor 1100 may execute a command or output corresponding image data to the display module 1400, on the basis of sensing data detected by the input sensor 1610-2 or the digitizer 1610-3. In the case where the sensor module 1610 includes a temperature sensor, the processor 1100 may receive temperature data regarding a measured temperature from the sensor module 1610 and further perform luminance correction on the image data, or the like on the basis of temperature data.

The processor 1100 may receive, from the camera module 1710, measurement data regarding the presence or absence of the user, the location of the user, the gaze of the user, and the like. The processor 1100 may further perform luminance correction on the image data, or the like on the basis of the measured data. For example, the processor 1100, which determines the presence or absence of the user through an input from the camera module 1710, may output, to the display module 1400, image data having luminance corrected through the data conversion circuit 1120-2 or the gamma correction circuit 1120-3.

Some of the components described above may be connected to each other through a communication method between peripheral devices, e.g., a bus, a general purpose input/output (GPIO), a serial peripheral interface (SPI), a mobile industry processor interface (MIPI), or an ultra path interconnect (UPI) link to exchange a signal (e.g., a command or data) with each other. The processor 1100 may communicate with the display module 1400 through a mutually agreed interface, e.g., may use any one of the communication methods described above, and is not limited to the communication methods described above.

The electronic device 1010 according to various embodiments provided herein may include various types of devices. The electronic device 1010 may include, for example, at least one of a portable communication device (e.g., a smartphone), a computer device, a portable multimedia device, a portable medical device, a camera, a wearable device, and a home appliance. The electronic device 1010 according to an embodiment is not limited to the devices mentioned above.

According to an embodiment, a display apparatus, which may be inspected for a defect in a dummy pixel through an AOI, may be provided.

However, the effect described above is an example and the effect of the disclosure is not limited thereto.

The respective embodiments described above are embodiments that may be independently implemented, but structures of the respective embodiments may be complexly applied to other embodiments.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A display apparatus comprising:
at least one light-emitting pixel in a display area of the display apparatus and comprising a plurality of sub-light-emitting pixels; and
at least one dummy pixel unit in a dummy area of the display apparatus, and connected to a repair line that is connected to at least one light-emitting device, the at least one dummy pixel unit comprising a plurality of sub-dummy pixels respectively corresponding to the plurality of sub-light-emitting pixels,
wherein a first sub-dummy pixel from among the plurality of sub-dummy pixels is a repair sub-dummy pixel, and
wherein a second sub-dummy pixel from among the plurality of sub-dummy pixels is an auxiliary sub-dummy pixel configured for an automatic optical inspection.

2. The display apparatus of claim 1, wherein, the first sub-dummy pixel is configured to be driven after a repair process, and the second sub-dummy pixel is configured not to be driven.

3. The display apparatus of claim 2, wherein, after the repair process, the first sub-dummy pixel is configured to be supplied with a first data signal through a data line, and the second sub-dummy pixel is configured to be supplied with a second data signal that is different from the first data signal through a dummy data line.

4. The display apparatus of claim 1, wherein the plurality of sub-dummy pixels comprise pixel circuits respectively corresponding to the plurality of sub-light-emitting pixels.

5. The display apparatus of claim 1, wherein the plurality of sub-dummy pixels do not comprise light-emitting devices respectively corresponding to the plurality of sub-light-emitting pixels.

6. The display apparatus of claim 1, wherein the at least one dummy pixel unit comprises a first layer and the at least one light-emitting pixel comprises a second layer, and
wherein the first layer has a same pattern and a same material as the second layer.

7. The display apparatus of claim 1, wherein a dummy pixel unit among the at least one dummy pixel unit that corresponds to the at least one light-emitting pixel is in a same row as the at least one light-emitting pixel.

8. The display apparatus of claim 7, wherein the at least one dummy pixel unit comprises a plurality of dummy pixel units corresponding to the at least one light-emitting pixel, and
wherein a first dummy pixel unit among the plurality of dummy pixel units is adjacent to a boundary of the display area, and a second dummy pixel unit among the plurality of dummy pixel units is adjacent to the first dummy pixel unit.

9. The display apparatus of claim 8, wherein the first dummy pixel unit comprises a repair sub-dummy pixel.

10. The display apparatus of claim 1, further comprising an additional sub-dummy pixel adjacent to the at least one dummy pixel unit.

11. The display apparatus of claim 1, wherein the at least one light-emitting pixel comprises a plurality of light-emitting pixels in the display area,
wherein, among the plurality of light-emitting pixels, a first light-emitting pixel and a second light-emitting pixel adjacent to the first light-emitting pixel comprise same patterns, and
wherein the at least one dummy pixel unit is adjacent to the display area and comprises a same pattern as the first light-emitting pixel and the second light-emitting pixel.

12. An electronic device comprising:
a controller configured to generate a scan input signal;
a power module configured to generate a scan input voltage; and
a display module comprising:
a display panel divided into a display area comprising a pixel circuit and a dummy area, and
a scan driver in the dummy area, the scan driver configured to receive the scan input signal and the scan input voltage, and output a scan signal to the pixel circuit,
wherein the display panel comprises:
a light-emitting pixel in the display area and comprising a plurality of sub-light-emitting pixels; and
at least one dummy pixel unit in the dummy area and connected to a repair line that is connected to at least one light-emitting device, the at least one dummy pixel unit comprising a plurality of sub-dummy pixels respectively corresponding to the plurality of sub-light-emitting pixels,
wherein a first sub-dummy pixel from among the plurality of sub-dummy pixels of the at least one dummy pixel unit is a repair sub-dummy pixel, and
wherein a second sub-dummy pixel from among the plurality of sub-dummy pixels is an auxiliary sub-dummy pixel configured for an automatic optical inspection.

13. The electronic device of claim 12, wherein, during a repair process, the first sub-dummy pixel is configured to be driven, and the second sub-dummy pixel is configured to be limitedly driven.

14. The electronic device of claim 13, wherein, during the repair process, the first sub-dummy pixel is configured to be supplied with a first data signal through a data line, and the second sub-dummy pixel is configured to be supplied with a second data signal that is different from the first data signal through a dummy data line.

15. The electronic device of claim 12, wherein the plurality of sub-dummy pixels comprise pixel circuits respectively corresponding to the plurality of sub-light-emitting pixels.

16. The electronic device of claim 12, wherein the plurality of sub-dummy pixels do not comprise light-emitting devices respectively corresponding to the plurality of sub-light-emitting pixels.

17. The electronic device of claim 12, wherein the at least one dummy pixel unit comprises a first layer and the light-emitting pixel comprises a second layer, and
wherein the first layer has a same pattern and a same material as the second layer.

18. The electronic device of claim 12, wherein a dummy pixel unit among the at least one dummy pixel unit that corresponds to the light-emitting pixel is in a same row as the light-emitting pixel.

19. The electronic device of claim 18, wherein the at least one dummy pixel unit comprises a plurality of dummy pixel units corresponding to the light-emitting pixel, and
wherein a first dummy pixel unit among the plurality of dummy pixel units is adjacent to a boundary of the display area, and a second dummy pixel unit among the plurality of dummy pixel units is adjacent to the first dummy pixel unit.

20. The electronic device of claim 19, wherein the first dummy pixel unit comprises a repair sub-dummy pixel.
